(19) United States
(12) Patent Application Publication
(10) Pub. No.: US 2025/0232916 A1
(43) Pub. Date: Jul. 17, 2025

(54) CAPACITOR AND METHOD FOR MANUFACTURING CAPACITOR

(71) Applicant: Panasonic Intellectual Property Management Co., Ltd., Osaka (JP)

(72) Inventors: Tomohiro FUJITA, Osaka (JP); Yosuke HAGIHARA, Osaka (JP); Kazushi YOSHIDA, Osaka (JP)

(73) Assignee: Panasonic Intellectual Property Management Co., Ltd., Osaka (JP)

(21) Appl. No.: 18/835,264

(22) PCT Filed: Jan. 25, 2023
(86) PCT No.: PCT/JP2023/002314

§ 371 Date: Apr. 4, 2025

(30) Foreign Application Priority Data
Feb. 4, 2022 (JP) 2022-016696

(51) Int. Cl. H01G 4/012

(52) U.S. Cl. CPC H01G 4/012

(57) ABSTRACT

A capacitor includes a silicon substrate, a conductive layer, a dielectric layer, and an electrode layer. The silicon substrate has a first principal surface and a second principal surface opposite the first principal surface. The silicon substrate has a porous silicon region including a plurality of pores formed in the first principal surface. The conductive layer is disposed along a surface of the porous silicon region. The dielectric layer has a shape along the surface of the porous silicon region and is disposed on the conductive layer. The electrode layer is disposed on the dielectric layer.

### TECHNICAL FIELD

The present disclosure relates to capacitors and methods for manufacturing the capacitors and specifically relates to a capacitor including a silicon substrate and a method for manufacturing the capacitor.

### BACKGROUND ART

Patent Literature 1 discloses a trench capacitor (capacitor). The capacitor disclosed in Patent Literature 1 includes a silicon substrate having a trench formed therein. The silicon substrate has an upper portion of a p⁻ silicon layer and a lower portion of a p⁺ silicon substrate. The trench is formed from the upper portion of the silicon substrate toward the lower portion. Moreover, the silicon substrate has a porous silicon region formed to surround a trench bottom and a trench side wall in the lower portion of the silicon substrate. In the capacitor disclosed in Patent Literature 1, the porous silicon region is disposed in the p⁺ silicon substrate and is not disposed in the p⁻ silicon layer. Moreover, the trench capacitor disclosed in Patent Literature 1 includes a dielectric layer conformally overlying the porous silicon region and a polysilicon layer conformally overlying the dielectric layer.

In the capacitor disclosed in Patent Literature 1, the porous silicon region forms a first polar plate, and the polysilicon layer forms a second polar plate.

In the capacitor disclosed in Patent Literature 1, applying a voltage which causes the potential of the polysilicon layer to be higher than the potential of the porous silicon region forms a depletion layer in the p⁻ silicon layer from an interface between the dielectric layer and the trench side wall layer in the p silicon. Thus, in the capacitor disclosed in Patent Literature 1, the capacitance of the capacitor varies depending on a difference in the polarity between voltages applied to both ends of the capacitor.

### CITATION LIST

### Patent Literature

Patent Literature 1: JP H08-213565 A

### SUMMARY OF INVENTION

It is an object of the present disclosure to provide a capacitor configured to have capacitance with reduced voltage-dependence and a method for manufacturing the capacitor.

A capacitor according to an aspect of the present disclosure includes a silicon substrate, a conductive layer, a dielectric layer, and an electrode layer. The silicon substrate has a first principal surface and a second principal surface opposite the first principal surface. The silicon substrate has a porous silicon region including a plurality of pores formed in the first principal surface. The conductive layer is disposed along a surface of the porous silicon region. The dielectric layer has a shape along the surface of the porous silicon region and is disposed on the conductive layer. The electrode layer is disposed on the dielectric layer.

A capacitor according to another aspect of the present disclosure includes a silicon substrate, a conductive layer, a dielectric layer, and an electrode layer. The silicon substrate has a first principal surface and a second principal surface opposite the first principal surface. The silicon substrate has a plurality of pores formed in the first principal surface and not reaching the second principal surface. The conductive layer has a shape along inner surfaces of the plurality of pores in the silicon substrate and covers the inner surfaces of the plurality of pores. The dielectric layer has a shape along the inner surfaces of the plurality of pores in the silicon substrate and covers the conductive layer. The electrode layer covers the dielectric layer.

A capacitor manufactured by a method for manufacturing a capacitor according to still another aspect of the present disclosure includes a silicon substrate, a conductive layer, a dielectric layer, and an electrode layer. The silicon substrate has a first principal surface and a second principal surface opposite the first principal surface. The silicon substrate has a porous silicon region including a plurality of pores formed in the first principal surface. The conductive layer is disposed along a surface of the porous silicon region. The dielectric layer has a shape along the surface of the porous silicon region and is disposed on the conductive layer. The electrode layer is disposed on the dielectric layer. The conductive layer is a diffusion layer disposed in the porous silicon region. The method for manufacturing the capacitor includes a first step, a second step, a third step, and a fourth step. The first step includes preparing the silicon substrate having the porous silicon region. The second step includes forming the conductive layer including the diffusion layer along the surface of the porous silicon region. The third step includes forming the dielectric layer on the conductive layer. The fourth step includes forming the electrode layer on the dielectric layer.

A capacitor manufactured by a method for manufacturing a capacitor according to yet another aspect of the present disclosure includes a silicon substrate, a conductive layer, a dielectric layer, and an electrode layer. The silicon substrate has a first principal surface and a second principal surface opposite the first principal surface. The silicon substrate has a porous silicon region including a plurality of pores formed in the first principal surface. The conductive layer is disposed along a surface of the porous silicon region. The dielectric layer has a shape along the surface of the porous silicon region and is disposed on the conductive layer. The electrode layer is disposed on the dielectric layer. The conductive layer is a metal layer formed on the surface of the porous silicon region. The method for manufacturing the capacitor includes a first step, a second step, a third step, and a fourth step. The first step includes preparing the silicon substrate having the porous silicon region. The second step includes forming the conductive layer including the metal layer on the surface of the porous silicon region. The third step includes forming the dielectric layer on the conductive layer. The fourth step includes forming the electrode layer on the dielectric layer.

### BRIEF DESCRIPTION OF DRAWINGS

FIG. 1 is a sectional view of a capacitor according to a first embodiment;

FIG. 2 is a plan view of the capacitor;

FIG. 3 is an enlarged sectional view of a main part of the capacitor.

FIGS. 4A to 4C are sectional views illustrating steps in a method for manufacturing the capacitor;

FIGS. 5A to 5D are sectional views illustrating steps in a method for manufacturing the capacitor;

FIG. 6 is an enlarged sectional view of a main part of a silicon substrate prepared in a first step of the method for manufacturing the capacitor;

FIG. 7 is a sectional view of a capacitor according to a second embodiment;

FIG. 8 is an enlarged sectional view of a main part of the capacitor according to the second embodiment;

FIGS. 9A to 9C are sectional views illustrating steps in a method for manufacturing the capacitor according to the second embodiment;

FIGS. 10A to 10D are sectional views illustrating steps in a method for manufacturing the capacitor according to the second embodiment; and

FIG. 11 is an enlarged sectional view of a main part of the capacitor according to a third embodiment.

### DESCRIPTION OF EMBODIMENTS

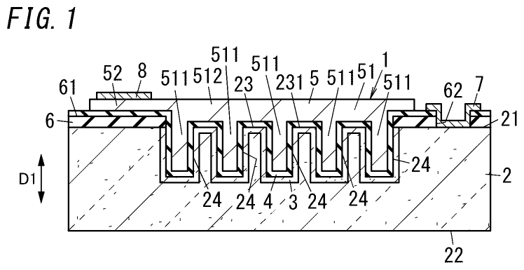

FIGS. 1 to 3, 4A to 4C, 5A to 5D, 6 to 8, 9A to 9C, 10A to 10D, and 11 to be described in first to third embodiments and the like below are schematic views, and the ratios of the size and thickness of each component in the figures do not necessarily reflect actual proportion.

### First Embodiment

### (1.1) Overview

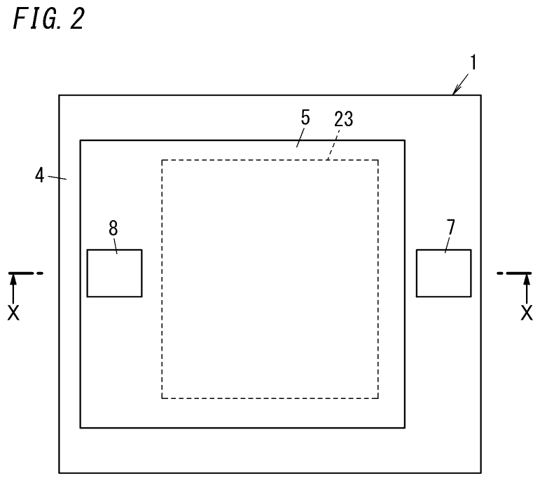

A capacitor 1 according to a first embodiment will be described below with reference to FIGS. 1 to 3. Note that FIG. 1 is a sectional view taken along line X-X of FIG. 2.

The capacitor 1 includes a silicon substrate 2, a conductive layer 3, a dielectric layer 4, and an electrode layer 5. The silicon substrate 2 has a first principal surface 21 and a second principal surface 22 opposite the first principal surface 21. The silicon substrate 2 has a porous silicon region 23 including a plurality of pores 24 formed in the first principal surface 21. The conductive layer 3 is disposed along a surface 231 of the porous silicon region 23. The dielectric layer 4 has a shape along the surface 231 of the porous silicon region 23 and is disposed on the conductive layer 3. The electrode layer 5 is disposed on the dielectric layer 4.

In the capacitor 1, the conductive layer 3 (and the silicon substrate 2) constitute a first electrode of the capacitor 1, the electrode layer 5 constitutes a second electrode of the capacitor 1, and the dielectric layer 4 constitutes a dielectric part interposed between the first electrode and the second electrode in the capacitor 1.

Moreover, the capacitor 1 further includes an insulating layer 6, a first external connection electrode 7, and a second external connection electrode 8. The insulating layer 6 is disposed on the first principal surface 21 of the silicon substrate 2. The insulating layer 6 surrounds the porous silicon region 23 when viewed in a thickness direction D1 defined with respect to the silicon substrate 2. The first external connection electrode 7 is connected to the conductive layer 3 via the silicon substrate 2. The second external connection electrode 8 is connected to the electrode layer 5.

### (1.2) Components of Capacitor

Components of the capacitor 1 will be described in further detail below.

### (1.2.1) Silicon Substrate

As shown in FIG. 1, the silicon substrate 2 has the first principal surface 21 and the second principal surface 22 opposite the first principal surface 21. An outer edge of the silicon substrate 2 when the silicon substrate 2 is viewed in the thickness direction D1 defined with respect to the silicon substrate 2 has a rectangular shape. The thickness of the silicon substrate 2 is, for example, greater than or equal to 300 μm and less than or equal to 1 mm.

The silicon substrate 2 is, for example, a p-type silicon substrate. When the silicon substrate 2 is the p-type silicon substrate, the silicon substrate 2 includes, for example, boron (B) as an impurity, but the impurity is not limited to this example, and the silicon substrate 2 may include indium (In) as the impurity.

The impurity concentration of the silicon substrate 2 is, for example, higher than or equal to 1×10¹³ cm⁻³ and lower than or equal to 1×10¹⁷ cm⁻³, and more preferably higher than or equal to 5×10¹³ cm⁻³ and lower than or equal to 5×10¹⁶ cm⁻³. The impurity concentration of the silicon substrate 2 is, for example, a value obtainable by secondary ion mass spectroscopy (SIMS).

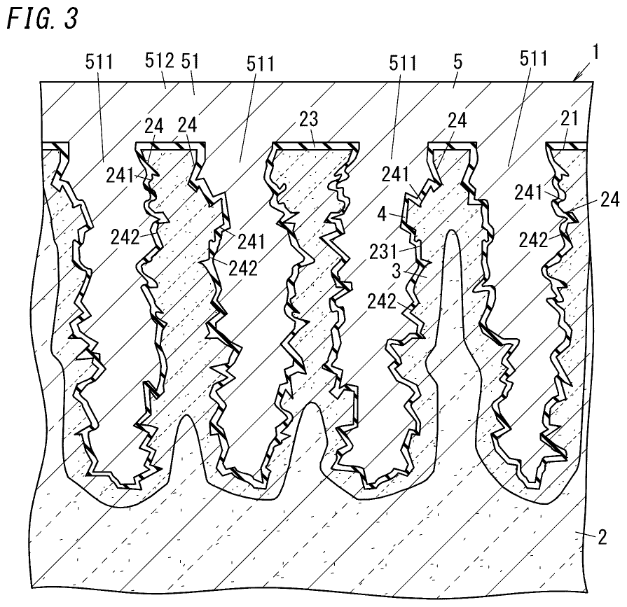

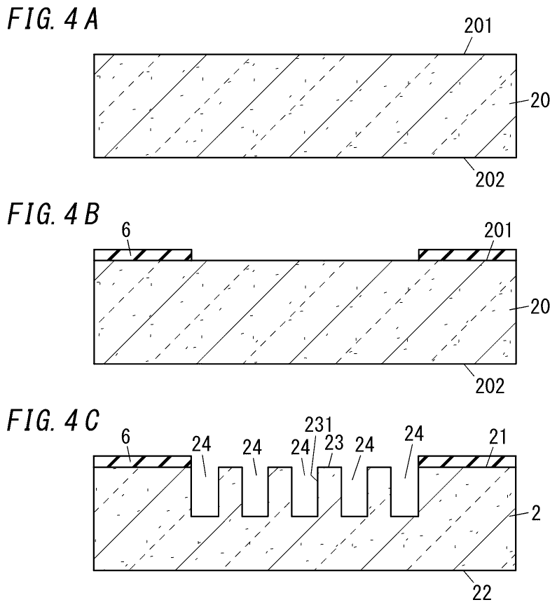

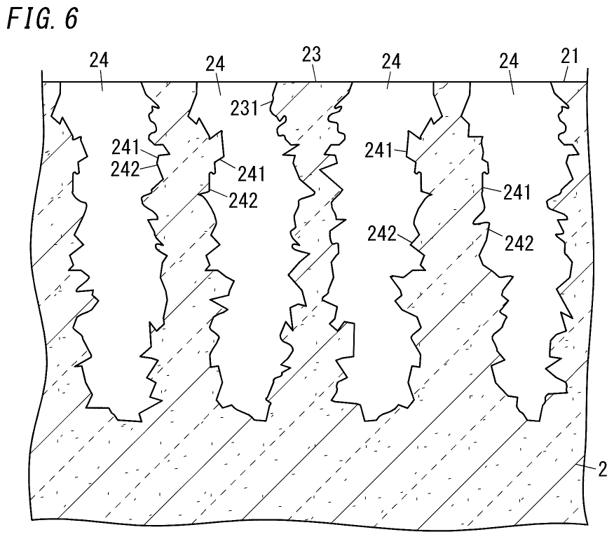

The silicon substrate 2 has the porous silicon region 23 including the plurality of pores 24 formed in the first principal surface 21. The surface 231 of the porous silicon region 23 includes inner surfaces 241 (see FIGS. 3 and 6) of the plurality of pores 24 formed in the first principal surface 21 of the silicon substrate 2 and part of the first principal surface 21 of the silicon substrate 2. The silicon substrate 2 having the porous silicon region 23 is for example, anodized part of a p-type monocrystalline silicon substrate 20 (see FIG. 4A). The plurality of pores 24 are in the first principal surface 21 of the silicon substrate 2 and do not reach the second principal surface 22. In other words, the plurality of pores 24 do not penetrate through the silicon substrate 2 in the thickness direction D1 defined with respect to the silicon substrate 2. The plurality of pores 24 are fine pores elongated in a direction along the thickness direction D1 defined with respect to the silicon substrate 2. More specifically, the plurality of pores 24 are fine pores each having a depth from the first principal surface 21 of the silicon substrate 2 in the thickness direction D1 defined with respect to the silicon substrate 2 and an opening width at the first principal surface 21 of the silicon substrate 2, and the depth is greater than the opening width. The opening width of each of the plurality of pores 24 at the first principal surface 21 of the silicon substrate 2 is, for example, greater than or equal to 0.1 μm and less than or equal to 10 μm. Moreover, the depth of each of the plurality of pores 24 is less than the thickness of the silicon substrate 2. The depth of each of the plurality of pores 24 in the thickness direction D1 defined with respect to the silicon substrate 2 is, for example, greater than or equal to 20 μm and less than or equal to 300 μm, and more preferably greater than or equal to 30 μm and less than or equal to 100 μm. Note that an upper limit value of the depth of each of the plurality of pores 24 is accordingly determined depending on, for example, the opening width of each of the plurality of pores 24 and the formation method of each of the conductive layer 3, the dielectric layer 4, and the electrode layer 5. The opening width and the depth of each of the pores 24 in the porous silicon region 23 of the silicon substrate 2 are, for example, values obtainable from a cross-sectional scanning electron microscope (SEM) image of the capacitor 1.

In the capacitor 1, the greater the depth of each of the plurality of pores 24 in the porous silicon region 23, the greater the surface area of the surface 231 of the porous silicon region 23 can be, and thus, the capacitor 1 can have increased capacitance. Moreover, in the capacitor 1, the larger the number of pores 24 in the porous silicon region 23, the greater the surface area of the surface 231 of the porous silicon region 23 can be.

In the silicon substrate 2, the surface 231 of the porous silicon region 23 includes the inner surfaces 241 (see FIG. 3) of the plurality of pores 24. Each of the inner surfaces 241 of the plurality of pores 24 in the porous silicon region 23 of the silicon substrate 2 includes a concave-convex surface 242 (see FIG. 3). A height difference between a crest and a trough at the concave-convex surface 242 is less than the opening width of each of the pores 24. The height difference between the crest and the trough at the concave-convex surface 242 is, for example, a value obtainable from a cross-sectional scanning electron microscope (SEM) image of the capacitor 1. The height difference between the crest and the trough at the concave-convex surface 242 can be varied depending on, for example, the impurity concentration of, and an anodization condition for, the p-type monocrystalline silicon substrate 20 (see FIG. 4A) from which the silicon substrate 2 is to be formed. Note that the impurity concentration of the silicon substrate 2 is the same as the impurity concentration of the p-type monocrystalline silicon substrate 20. Moreover, the carrier concentration of the silicon substrate 2 is the same as the carrier concentration of the p-type monocrystalline silicon substrate 20.

When viewed in the thickness direction D1 defined with respect to the silicon substrate 2, the porous silicon region 23 is a quadrangular region and is surrounded by the insulating layer 6. The porous silicon region 23 is not limited to the quadrangular region when viewed in the thickness direction D1 defined with respect to the silicon substrate 2 but may be, for example, a circular region, may be a polygonal region other than the quadrangle, or may have a polygonal shape other than a convex polygon. Moreover, when viewed in the thickness direction D1 defined with respect to the silicon substrate 2, part of the porous silicon region 23 may overlap the insulating layer 6.

### (1.2.2) Conductive Layer

As shown in FIGS. 1 and 3, the conductive layer 3 is disposed along the surface 231 of the porous silicon region 23. In the capacitor 1 according to the first embodiment, the conductive layer 3 is a diffusion layer disposed in the porous silicon region 23 of the silicon substrate 2. The electrically conductive type of the diffusion layer included in the conductive layer 3 is the same as the electrically conductive type of the silicon substrate 2. Moreover, the impurity concentration of the diffusion layer is higher than the impurity concentration of the silicon substrate 2. Thus, when the silicon substrate 2 is the p-type silicon substrate, the diffusion layer is a p-type silicon region (p⁺ silicon region) having a higher concentration than the p-type silicon substrate. The type of the impurity in the diffusion layer is, for example, the same as the type of the impurity in the silicon substrate 2. More specifically, when the silicon substrate 2 is the p-type silicon substrate and the impurity in the silicon substrate 2 is boron, the impurity in the diffusion layer is boron. The impurity concentration of the diffusion layer is higher than or equal to 1×10¹⁸ cm⁻³ and lower than or equal to 1×10²¹ cm⁻³, and more preferably higher than or equal to 5×10¹⁸ cm⁻³ and lower than or equal to 1×10²⁰ cm⁻³. The impurity concentration of the diffusion layer is, for example, a value obtainable by SIMS.

The carrier concentration of the conductive layer 3 is higher than the carrier concentration of the silicon substrate 2. The carrier concentration of the conductive layer 3 and the carrier concentration of the silicon substrate 2 are, for example, values obtainable by carrier concentration distribution observation using a scanning microwave impedance microscope (sMIM).

For discussion about the relative high/low relationship between the carrier concentration of the conductive layer 3 and the carrier concentration of the silicon substrate 2, the carrier concentrations are not limited to the values obtainable by the carrier concentration distribution observation using the sMIM. The carrier concentration of the conductive layer 3 and the carrier concentration of the silicon substrate 2 may be, for example, values obtainable by carrier concentration distribution observation by scanning capacitance microscopy (SCM). Moreover, the carrier concentration of the conductive layer 3 and the carrier concentration of the silicon substrate 2 may be, for example, values obtainable by carrier concentration distribution observation by scanning nonlinear dielectric microscopy (SNDM).

The thickness of the diffusion layer is greater than or equal to 10 nm and less than or equal to 10000 nm, and more preferably greater than or equal to 50 nm and less than or equal to 5000 nm. The thickness of the diffusion layer is, for example, a value obtainable by observing the cross-section surface of the capacitor 1 using a scanning microwave impedance microscope (sMIM). The thickness of the diffusion layer is the thickness of the diffusion layer in a normal direction at an arbitrary point of the inner surfaces 241 (see FIG. 3) of the pores 24.

### (1.2.3) Dielectric Layer

As shown in FIGS. 1 and 3, the dielectric layer 4 is disposed on the conductive layer 3 and has a shape along the surface 231 of the porous silicon region 23. The dielectric layer 4 has a portion interposed between the conductive layer 3 and the electrode layer 5 in the thickness direction D1 defined with respect to the silicon substrate 2 and portions interposed between the conductive layer 3 and the electrode layer 5 in the plurality of pores 24 formed in the porous silicon region 23.

The thickness of the dielectric layer 4 is, for example, greater than or equal to 10 nm and less than or equal to 500 nm. An upper limit of the thickness of the dielectric layer 4 is limited by, for example, the opening width of each of the pores 24 in the porous silicon region 23 in one direction along the first principal surface 21 of the silicon substrate 2 and the thickness of the electrode layer 5 in each of the pores 24 in the porous silicon region 23 in the one direction.

The dielectric layer 4 has a multilayer structure including a plurality of dielectric films stacked on top of another but is not limited to this example, and the dielectric layer 4 may be a single dielectric layer. When the dielectric layer 4 has the multilayer structure, the dielectric layer 4 includes, for example, a first dielectric film (e.g., first silicon oxide film) on the conductive layer 3, a second dielectric film (e.g., silicon nitride film) on the first dielectric film, and a third dielectric film (e.g., second silicon oxide film) on the second dielectric film. A material for the first silicon oxide film and the second silicon oxide film is, for example, silicon dioxide (SiO₂). It is not essential that the composition of each of the first silicon oxide film and the second silicon oxide film is strictly SiO₂. Moreover, the composition of the first silicon oxide film and the composition of the second silicon oxide film may be different from each other. When the dielectric layer 4 consists of a single dielectric film, a material for the dielectric film is for example, silicon oxide. A material for the dielectric film is not limited to the silicon oxide but may be, for example, titanium oxide, zirconium oxide, hafnium oxide, vanadium oxide, tungsten oxide, niobium oxide, tantalum oxide or aluminum oxide.

The dielectric layer 4 extends over both the conductive layer 3 and a principal surface 61 on an opposite side of the insulating layer 6 from the silicon substrate 2.

### (1.2.4) Electrode Layer

As shown in FIGS. 1 and 3, the electrode layer 5 is disposed on the dielectric layer 4. The electrode layer 5 is, for example, a conductive polycrystalline silicon layer. The impurity concentration of the conductive polycrystalline silicon layer is, for example, higher than or equal to 1×10¹⁸ cm⁻³ and lower than or equal to 1×10²¹ cm⁻³, and more preferably higher than or equal to 5×10¹⁸ cm⁻³ and lower than or equal to 1×10²⁰ cm⁻³. An impurity in the conductive polycrystalline silicon layer includes one selected from the group consisting of, for example, boron, indium, phosphorus, arsenic, and antimony. The electrode layer 5 is not limited to the conductive polycrystalline silicon layer but may be, for example, a metal electrode layer. A material for the metal electrode layer includes at least one selected from the group consisting of, for example, ruthenium (Ru), titanium (Ti), tantalum (Ta), tungsten (W), and aluminum (Al). More specifically, the material for the metal electrode layer is, for example, ruthenium, titanium, tantalum, tungsten, aluminum, or an alloy including any of these metals as a main component.

The electrode layer 5 has: a first portion 51 facing the conductive layer 3 with the dielectric layer 4 disposed between the electrode layer 5 and the conductive layer 3; and a second portion 52 located on the principal surface 61 of the insulating layer 6. The first portion 51 of the electrode layer 5 includes a plurality of columnar portions 511 located in the plurality of pores 24 in the porous silicon region 23 of the silicon substrate 2 and a portion 512 which connects upper ends of the plurality of columnar portions 511 to each other.

### (1.2.5) Insulating Layer

As shown in FIG. 1, the insulating layer 6 is disposed on the first principal surface 21 of the silicon substrate 2. The insulating layer 6 surrounds the porous silicon region 23 when viewed in the thickness direction D1 defined with respect to the silicon substrate 2. The insulating layer 6 includes, for example, a silicon oxide layer formed on the first principal surface 21 of the silicon substrate 2 and a silicon nitride layer formed on the silicon oxide layer.

The thickness of the silicon oxide layer is, for example, greater than or equal to 0.5 μm and less than or equal to 2 μm and is, for example, 1 μm. The thickness of the silicon nitride layer is, for example, greater than or equal to 0.5 μm and less than or equal to 2 μm and is, for example, 1 μm. The thickness of the silicon nitride layer is the same as the thickness of the silicon oxide layer but is not limited to this example, and the thickness of the silicon nitride layer may be a thickness different from the thickness of the silicon oxide layer.

The insulating layer 6 is not limited to having the layered structure of the silicon oxide layer and the silicon nitride layer but may have a single layer structure consisting of, for example, a silicon oxide layer.

### (1.2.6) First External Connection Electrode and Second External Connection Electrode

As shown in FIG. 1, the first external connection electrode 7 is connected to the conductive layer 3 via the silicon substrate 2. More specifically, the first external connection electrode 7 is connected to the first principal surface 21 of the silicon substrate 2 through a contact hole 62 formed in the insulating layer 6 and is connected to the conductive layer 3 via the silicon substrate 2. In the capacitor 1, the first external connection electrode 7 is electrically connected to the silicon substrate 2. Saying that “the first external connection electrode 7 is electrically connected to the silicon substrate 2” means that the first external connection electrode 7 and the silicon substrate 2 are in ohmic contact with each other. When viewed in the thickness direction D1 defined with respect to the silicon substrate 2, an outer edge of the first external connection electrode 7 has, for example, a quadrangular shape but is not limited to this example, and the outer edge may have, for example, a circular shape. The first external connection electrode 7 extends over part of the first principal surface 21 of the silicon substrate 2, an inner peripheral surface of the contact hole 62 in the insulating layer 6, and part of the principal surface 61 of the insulating layer 6. The first external connection electrode 7 does not overlap the porous silicon region 23 in the thickness direction D1 defined with respect to the silicon substrate 2.

The second external connection electrode 8 is connected to the electrode layer 5. In the capacitor 1, the second external connection electrode 8 is electrically connected to the electrode layer 5. Saying that “the second external connection electrode 8 is electrically connected to the electrode layer 5” means that the second external connection electrode 8 and the electrode layer 5 are in ohmic contact with each other. The second external connection electrode 8 is disposed on part of the second portion 52, which is disposed on the principal surface 61 of the insulating layer 6, of the electrode layer 5. The second external connection electrode 8 does not overlap the porous silicon region 23 in the thickness direction D1 defined with respect to the silicon substrate 2.

A material for the first external connection electrode 7 and the second external connection electrode 8 includes, for example, aluminum but is not limited to this example, and the material may include, for example, gold, platinum, and ruthenium. The material for the second external connection electrode 8 is the same as the material for the first external connection electrode 7 but is not limited to this example, and the material may be a material different from the material for the first external connection electrode 7.

The thickness of each of the first external connection electrode 7 and the second external connection electrode 8 is, for example, greater than or equal to 1 μm and less than or equal to 3 μm. The thickness of the second external connection electrode 8 is the same as the thickness of the first external connection electrode 7 but is not limited to this example, and the thickness may be a thickness different from the thickness of the first external connection electrode 7.

### (1.3) Method for Manufacturing Capacitor

As a method for manufacturing the capacitor 1, for example, a manufacturing method including a first step, a second step, a third step, and a fourth step may be employed. The method for manufacturing the capacitor 1 further includes a fifth step. The method for manufacturing the capacitor 1 will be described below with reference to FIGS. 4A to 4C, 5A to 5D, and 6.

In the first step, the silicon substrate 2 (see FIGS. 4C and 6) is prepared. The silicon substrate 2 has the first principal surface 21 and the second principal surface 22 opposite the first principal surface 21 and has the porous silicon region 23 including the plurality of pores 24 formed in the first principal surface 21.

In the first step, the p-type monocrystalline silicon substrate 20 (see FIG. 4A) from which the silicon substrate 2 is to be formed is prepared first. The p-type monocrystalline silicon substrate 20 has a first principal surface 201 and a second principal surface 202 opposite the first principal surface 201. The first principal surface 201 of the p-type monocrystalline silicon substrate 20 is, for example, a (100) plane but is not limited to this example, and the first principal surface 201 may be, for example, a (110) plane or a (111) plane. Moreover, the first principal surface 201 of the p-type monocrystalline silicon substrate 20 may be, for example, a crystal plane having an off angle of greater than 0° and less than or equal to 5° from the (100) plane. Here, the “off angle” is a tilt angle of the first principal surface 201 with respect to the (100) plane. Thus, when the off angle is 0°, the first principal surface 201 is the (100) plane.

In the first step, the insulating layer 6 (see FIG. 4B) having a predetermined pattern is formed on the first principal surface 201 of the p-type monocrystalline silicon substrate 20. Thereafter, in the first step, anodization is performed by using the p-type monocrystalline silicon substrate 20 as an anode, thereby forming the silicon substrate 2 (see FIGS. 4C and 6) having the porous silicon region 23. Note that to form the insulating layer 6 having the predetermined pattern, for example, the first step and the second step are performed. In the first step, a silicon oxide layer is formed by, for example, thermal oxidation on the entirety of the first principal surface 201 of the p-type monocrystalline silicon substrate 20, and a silicon nitride layer is formed on the silicon oxide layer by, for example, chemical vapor deposition (CVD). In the second step, a layered structure of the silicon oxide layer and the silicon nitride layer is patterned into the predetermined pattern by a photolithography technique and an etching technique, thereby forming the insulating layer 6. Here, the first principal surface 201 of the p-type monocrystalline silicon substrate 20 corresponds to the first principal surface 21 of the silicon substrate 2.

In the first step, as described above, the anodization is performed on the p-type monocrystalline silicon substrate 20, thereby forming the silicon substrate 2 having the porous silicon region 23 (see FIGS. 4C and 6). In the anodization, a platinum electrode is arranged to face the first principal surface 201 of the p-type monocrystalline silicon substrate 20 in an electrolytic solution, and a current having a predetermined current density is allowed to flow for a predetermined amount of time between an anode as which the p-type monocrystalline silicon substrate 20 is used and a cathode as which the platinum electrode is used. Thus, the anodization makes the p-type monocrystalline silicon substrate 20 porous in a region which is part of the first principal surface 201 of the p-type monocrystalline silicon substrate 20 and which is not covered with the insulating layer 6. In the first step, the silicon substrate 2 having the porous silicon region 23 including the plurality of pores 24 is thus prepared. The electrolytic solution is, for example, a mixed liquid of hydrofluoric acid and ethanol. Note that before the anodization is performed, an electrode to be used in the anodization is formed on the second principal surface 202 of the p-type monocrystalline silicon substrate 20. This electrode may be removed after the anodization or may be left without being removed. The electrode may be a metal film or a high impurity concentration layer having a higher impurity concentration than the silicon substrate 2.

In the first step, changing at least one of the concentration of hydrogen fluoride in the electrolytic solution, the predetermined current density, or the predetermined amount of time enables the shape and the depth of each of the plurality of pores 24 to be controlled. The concentration of hydrogen fluoride in the electrolytic solution is, for example, higher than or equal to 1 wt % and lower than or equal to 80 wt %, and more preferably higher than or equal to 20 wt % and lower than or equal to 40 wt %. Moreover, in the method for manufacturing the capacitor 1, changing the resistivity of the p-type monocrystalline silicon substrate 20 also enables the shape of each of the plurality of pores 24 to be controlled, the resistivity of the p-type monocrystalline silicon substrate 20 being determined based on the impurity concentration of the p-type monocrystalline silicon substrate 20 from which the silicon substrate 2 is to be formed.

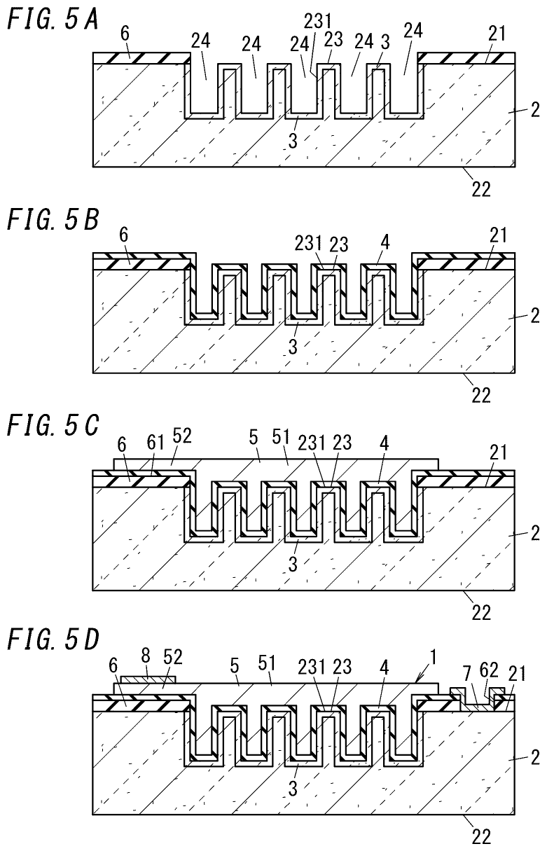

In the second step, the conductive layer 3 including a diffusion layer along the surface 231 of the porous silicon region 23 of the silicon substrate 2 is formed as shown in FIG. 5A. In the second step, for example, an impurity (e.g., boron) is thermally diffused in the porous silicon region 23 of the silicon substrate 2 by using the insulating layer 6 as a mask layer, thereby forming the conductive layer 3 including the diffusion layer having a higher impurity concentration than the silicon substrate 2.

In the third step, the dielectric layer 4 is formed on the conductive layer 3 as shown in FIG. 5B. In the third step, the first silicon oxide film of the dielectric layer 4 is formed by, for example, CVD, the silicon nitride film of the dielectric layer 4 is formed by, for example, CVD, and the second silicon oxide film of the dielectric layer 4 is formed by, for example, CVD. Note that the first silicon oxide film may be formed by thermal oxidation. In this case, the first silicon oxide film is not formed on the insulating layer 6.

In the fourth step, the electrode layer 5 is formed on the dielectric layer 4 as shown in FIG. 5C. More specifically, in the fourth step, an electrode material layer from which the electrode layer 5 is to be formed is formed on the dielectric layer 4 first. In the fourth step, the electrode material layer is formed by, for example, CVD, and thereafter, the electrode material layer is patterned by, for example, the photolithography technique and the etching technique, thereby forming the electrode layer 5 including part of the electrode material layer. The electrode layer 5 includes the first portion 51 overlapping the porous silicon region 23 and the second portion 52 located on the principal surface 61 of the insulating layer 6 in the thickness direction D1 (see FIG. 1) defined with respect to the silicon substrate 2.

In the fifth step, the first external connection electrode 7 and the second external connection electrode 8 are formed as shown in FIG. 5D. Specifically, in the fifth step, the contact hole 62 is formed in the insulating layer 6, thereby exposing part of the first principal surface 21 of the silicon substrate 2 first. In the fifth step, the contact hole 62 is formed by using, for example, the photolithography technique and the etching technique. Thereafter, the first external connection electrode 7 and the second external connection electrode 8 are formed by using, for example, a thin film formation method, the photolithography technique, and the etching technique. The thin film formation method is, for example, evaporation, sputtering, or CVD. The fifth step may include heat treatment for obtaining an ohmic contact between the first external connection electrode 7 and the silicon substrate 2.

In the method for manufacturing the capacitor 1, a first wafer (e.g., silicon wafer) including a plurality of p-type monocrystalline silicon substrates 20 is prepared in the first step, and the first to fifth steps are performed, thereby obtaining a second wafer including a plurality of capacitors 1. In the method for manufacturing the capacitor 1, the second wafer is cut by, for example, a dicing saw or a laser dicing device, thereby obtaining the plurality of capacitors 1.

### (2) Advantages

### (2.1) Capacitor

The capacitor 1 according to the first embodiment includes the silicon substrate 2, the conductive layer 3, the dielectric layer 4, and the electrode layer 5. The silicon substrate 2 has the first principal surface 21 and the second principal surface 22 opposite the first principal surface 21. The silicon substrate 2 has the porous silicon region 23 including the plurality of pores 24 formed in the first principal surface 21. The conductive layer 3 is disposed along the surface 231 of the porous silicon region 23. The dielectric layer 4 has a shape along the surface 231 of the porous silicon region 23 and is disposed on the conductive layer 3. The electrode layer 5 is disposed on the dielectric layer 4. The capacitor 1 according to the first embodiment includes the conductive layer 3 disposed along the surface 231 of the porous silicon region 23, and therefore, the conductive layer 3 extends over both the inner surfaces 241 of the plurality of pores 24 in the porous silicon region 23 and the first principal surface 21. Thus, the capacitor 1 according to the first embodiment is configured to have capacitance with reduced voltage-dependence. More specifically, since the capacitor 1 according to the first embodiment includes the conductive layer 3, a depletion layer can be suppressed from being formed from the dielectric layer 4 at the side of the silicon substrate 2 (the width of the depletion layer can be reduced) when the potential of the electrode layer 5 is higher than the potential of the silicon substrate 2. Therefore, the capacitor 1 according to the first embodiment is configured to have a reduced difference between the capacitance when the potential of the electrode layer 5 is lower than the potential of the silicon substrate 2 and the capacitance when the potential of the electrode layer 5 is higher than the potential of the silicon substrate 2. In other words, in the capacitor 1 according to the first embodiment, the capacitance of the capacitor 1 can be suppressed from varying depending on a difference in the polarity between voltages applied to both ends of the capacitor 1. Moreover, in the capacitor 1 according to the first embodiment, the inner surfaces 241 of the plurality of pores 24 in the porous silicon region 23 include the concave-convex surfaces 242, and therefore, the surface 231 of the porous silicon region 23 has an increased area, and the capacitance of the capacitor 1 is thus easily increased.

Moreover, the capacitor 1 according to the first embodiment does not have to employ an epitaxial substrate having an upper portion including a p⁻ silicon layer and a lower portion including a p⁺ silicon substrate unlike the silicon substrate disclosed in the Patent Literature 1, and therefore, the conductive layer 3 has an increased surface area. Moreover, the capacitor 1 according to the first embodiment does not have to employ an epitaxial substrate such as the silicon substrate disclosed in Patent Literature 1 and can thus be reduced in cost.

Moreover, in the capacitor 1 according to the first embodiment, the conductive layer 3 is the diffusion layer formed along the surface 231 of the porous silicon region 23 of the silicon substrate 2. Thus, the capacitor 1 according to the first embodiment does not have to form the conductive layer 3 in the plurality of pores 24 in the porous silicon region 23 and has the advantage that the dielectric layer 4 and the electrode layer 5 are easily formed in the plurality of pores 24.

### (2.2) Method for Manufacturing Capacitor

The method for manufacturing the capacitor 1 according to the first embodiment includes: preparing the silicon substrate 2 having the porous silicon region 23; forming the conductive layer 3 including a diffusion layer along the surface 231 of the porous silicon region 23; thereafter, forming the dielectric layer 4 on the conductive layer 3; and thereafter, forming the electrode layer 5 on the dielectric layer 4. The method for manufacturing the capacitor 1 according to the first embodiment enables the voltage-dependence of the capacitance to be reduced.

### (3) Variations of First Embodiment

The silicon substrate 2 is not limited to the p-type silicon substrate but may be an n-type silicon substrate. When the silicon substrate 2 is the n-type silicon substrate, the silicon substrate 2 includes, for example, phosphorus (P) as an impurity, but the impurity is not limited to this example, and the silicon substrate 2 may include arsenic (As) or antimony (Sb) as the impurity.

Moreover, also when the silicon substrate 2 is the n-type silicon substrate, the impurity concentration of the diffusion layer is higher than the impurity concentration of the silicon substrate 2. Moreover, the carrier concentration of the diffusion layer is higher than the carrier concentration of the silicon substrate 2. The diffusion layer includes, for example, phosphorus (P) as the impurity, but the impurity is not limited to this example, and the diffusion layer may include arsenic (As) or antimony (Sb) as the impurity.

When the silicon substrate 2 is the n-type silicon substrate, the method for manufacturing the capacitor 1 is substantially the same as the method for manufacturing the capacitor 1 according to the first embodiment. However, in the first step, in order to form the porous silicon region 23 by anodization, an n-type monocrystalline silicon substrate from which the silicon substrate 2 is to be formed is irradiated with light to increase holes in the n-type monocrystalline silicon substrate.

### Second Embodiment

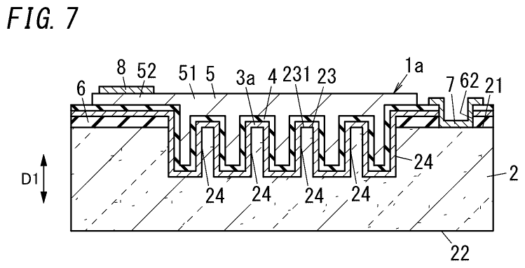

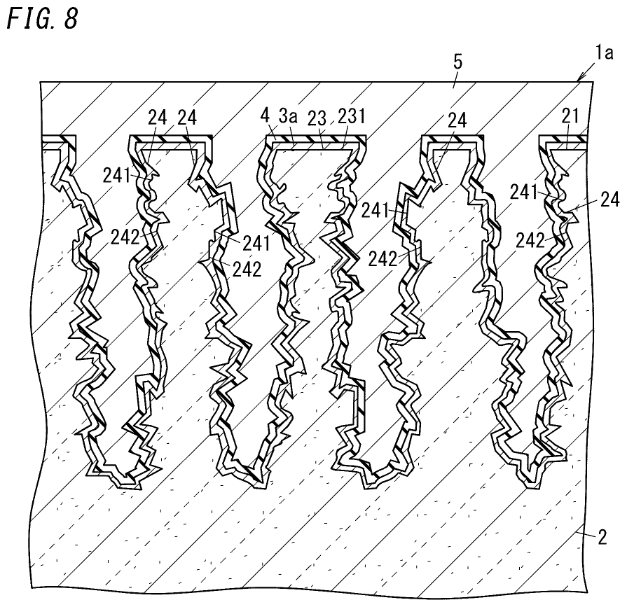

A capacitor 1a according to a second embodiment will be described below with reference to FIGS. 7 and 8.

The capacitor 1a according to the second embodiment is different from the capacitor 1 according to the first embodiment in that the capacitor 1a includes a conductive layer 3a in place of the conductive layer 3 in the capacitor 1 according to the first embodiment.

The conductive layer 3a is a metal layer disposed on a surface 231 of a porous silicon region 23. A material for the metal layer includes at least one selected from the group consisting of, for example, ruthenium, titanium, tantalum, tungsten, and aluminum. The thickness of the metal layer is, for example, greater than or equal to 3 nm and less than or equal to 1000 nm. The thickness of the metal layer is a value obtainable from a cross-sectional scanning electron microscope (SEM) image of the capacitor 1a. The thickness of the metal layer is the thickness of the metal layer in a normal direction at an arbitrary point of the surface 231 of the porous silicon region 23. An upper limit of the thickness of the metal layer is limited by, for example, the opening width of each of pores 24 in the porous silicon region 23 in one direction along a first principal surface 21 of a silicon substrate 2 and the thickness of a dielectric layer 4 and the thickness of an electrode layer 5 in each of the pores 24 in the porous silicon region 23 in the one direction.

The capacitor 1a according to the second embodiment is configured to have capacitance with reduced voltage-dependence. The capacitor 1a according to the second embodiment includes the conductive layer 3a disposed along the surface 231 of the porous silicon region 23, and therefore, the conductive layer 3a extends over both the first principal surface 21 and inner surfaces 241 of the plurality of pores 24 in the porous silicon region 23. Thus, the capacitor 1a according to the second embodiment is configured to have capacitance with reduced voltage-dependence. More specifically, the capacitor 1a according to the second embodiment is configured to have a reduced difference between the capacitance when the potential of the electrode layer 5 is lower than the potential of the silicon substrate 2 and the capacitance when the potential of the electrode layer 5 is higher than the potential of the silicon substrate 2.

In the capacitor 1a according to the second embodiment, no depletion layer extending from an interface between the dielectric layer 4 and the conductive layer 3a toward the conductive layer 3a is formed when the conductive layer 3a is a metal layer and the potential of the electrode layer 5 is higher than the potential of the silicon substrate 2. Thus, the capacitor 1a according to the second embodiment is configured to have capacitance with further reduced voltage-dependence as compared with the capacitor 1 according to the first embodiment.

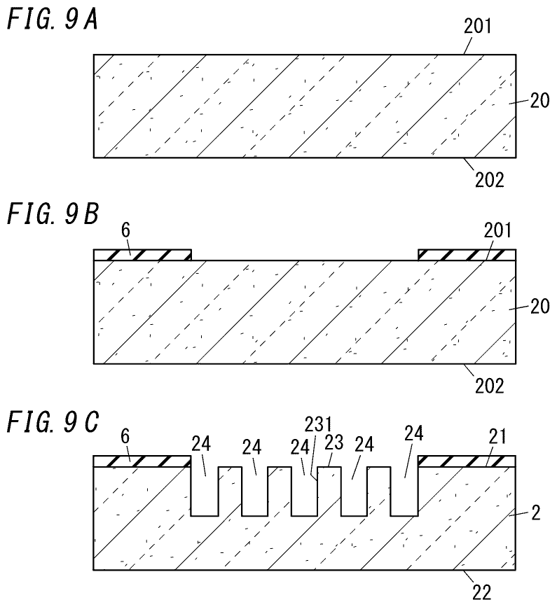

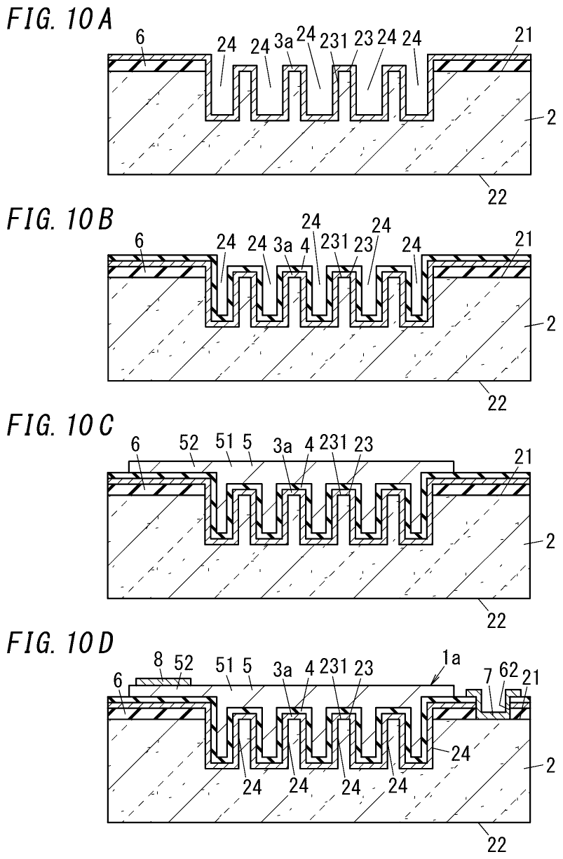

As a method for manufacturing the capacitor 1a according to the second embodiment, for example, a manufacturing method including a first step, a second step, a third step, and a fourth step may be employed. The method for manufacturing the capacitor 1a further includes a fifth step. The method for manufacturing the capacitor 1a will be described below with reference to FIGS. 9A to 9C and 10A to TOD. The method for manufacturing the capacitor 1a according to the second embodiment is substantially the same as the method for manufacturing the capacitor 1 according to the first embodiment and is different only in that the conductive layer 3a is formed in place of the conductive layer 3 in the second step. Regarding the method for manufacturing the capacitor 1a according to the second embodiment, the description of steps similar to those in the method for manufacturing the capacitor 1 according to the first embodiment will accordingly be omitted.

In the first step, the silicon substrate 2 (see FIG. 9C) is prepared. The silicon substrate 2 has the first principal surface 21 and a second principal surface 22 opposite the first principal surface 21 and has the porous silicon region 23 including the plurality of pores 24 formed in the first principal surface 21.

In the first step, a p-type monocrystalline silicon substrate 20 (see FIG. 9A) from which the silicon substrate 2 is to be formed is prepared first. The p-type monocrystalline silicon substrate 20 has a first principal surface 201 and a second principal surface 202 opposite the first principal surface 201.

In the first step, the insulating layer 6 (see FIG. 9B) having a predetermined pattern is formed on the first principal surface 201 of the p-type monocrystalline silicon substrate 20, and anodization is performed by using the p-type monocrystalline silicon substrate 20 as an anode, thereby forming the silicon substrate 2 (see FIG. 9C) having the porous silicon region 23.

In the second step, the conductive layer 3a including a metal layer is formed on the surface 231 of the porous silicon region 23 of the silicon substrate 2 as shown in FIG. 10A. In the second step, the conductive layer 3a including the metal layer is formed on the surface 231 of the porous silicon region 23 by, for example, CVD or atomic layer deposition (ALD).

In the third step, the dielectric layer 4 is formed on the conductive layer 3a as shown in FIG. 10B.

In the fourth step, the electrode layer 5 is formed on the dielectric layer 4 as shown in FIG. 10C.

In the fifth step, a first external connection electrode 7 and a second external connection electrode 8 are formed as shown in FIG. 10D.

In the method for manufacturing the capacitor 1a, a first wafer (e.g., silicon wafer) including a plurality of p-type monocrystalline silicon substrates is prepared in the first step, and the first to fifth steps are performed, thereby obtaining a second wafer including a plurality of capacitors 1a. In the method for manufacturing the capacitor 1a, the second wafer is cut by, for example, a dicing saw or a laser dicing device, thereby obtaining the plurality of capacitors 1a.

The method for manufacturing the capacitor 1a according to the second embodiment includes: preparing the silicon substrate 2 having the porous silicon region 23; thereafter, forming the conductive layer 3a including a metal layer on the surface 231 of the porous silicon region 23; thereafter, forming the dielectric layer 4 on the conductive layer 3a; and thereafter, forming the electrode layer 5 on the dielectric layer 4. The method for manufacturing the capacitor 1a according to the second embodiment enables the voltage-dependence of the capacitance to be reduced.

In the capacitor 1a according to the second embodiment, from the other perspective, the silicon substrate 2 has the plurality of pores 24 formed in the first principal surface 21 and not reaching the second principal surface 22. The conductive layer 3a has a shape along the inner surfaces 241 of the plurality of pores 24 in the silicon substrate 2 and covers the inner surfaces 241 of the plurality of pores 24. The dielectric layer 4 has a shape along the inner surfaces 241 of the plurality of pores 24 in the silicon substrate 2 and covers the conductive layer 3a. The electrode layer 5 covers the dielectric layer 4. Thus, the capacitor 1a according to the second embodiment includes the conductive layer 3a and thus is configured to have capacitance with reduced voltage-dependence. Moreover, since the silicon substrate 2 has the porous silicon region 23, the capacitor 1a according to the second embodiment can have further increased capacitance.

### Third Embodiment

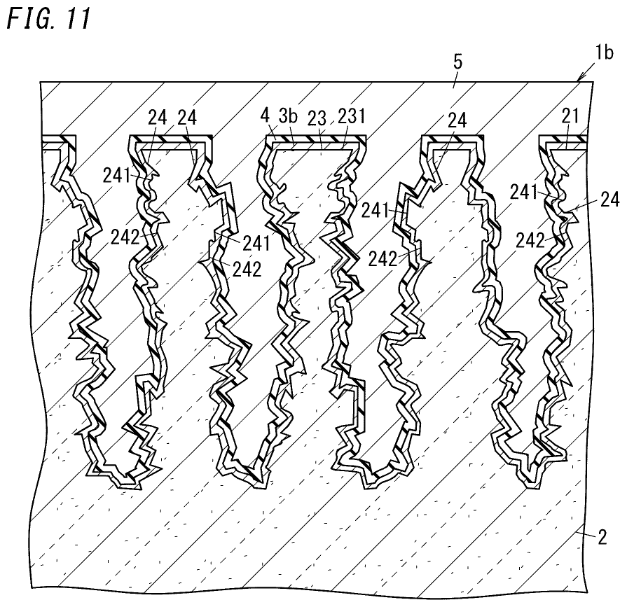

A capacitor 1b according to a third embodiment will be described below with reference to FIG. 11.

The capacitor 1b according to the third embodiment is different from the capacitor 1 according to the first embodiment in that the capacitor 1b includes a conductive layer 3b in place of the conductive layer 3 in the capacitor 1 according to the first embodiment.

The conductive layer 3b is a conductive polycrystalline silicon layer disposed on a surface 231 of a porous silicon region 23. In the capacitor 1b, the impurity concentration of the conductive polycrystalline silicon layer is higher than the impurity concentration of a silicon substrate 2. In the capacitor 1b, the impurity concentration of the silicon substrate 2 is higher than or equal to 1×10¹³ cm⁻³ and lower than or equal to 1×10¹⁷ cm⁻³, and the impurity concentration of the conductive polycrystalline silicon layer is higher than or equal to 1×10¹⁸ cm⁻³ and lower than or equal to 1×10²¹ cm⁻³.

The capacitor 1b according to the third embodiment is configured to have capacitance with reduced voltage-dependence. The capacitor 1b according to the third embodiment includes the conductive layer 3b disposed along the surface 231 of the porous silicon region 23, and therefore, the conductive layer 3b extends over both inner surfaces 241 of a plurality of pores 24 in the porous silicon region 23 and a first principal surface 21. Thus, the capacitor 1b according to the third embodiment is configured to have capacitance with reduced voltage-dependence. More specifically, the capacitor 1b according to the third embodiment has a reduced difference between the capacitance when the potential of the electrode layer 5 is lower than the potential of the silicon substrate 2 and the capacitance when the potential of the electrode layer 5 is higher than the potential of the silicon substrate 2. The capacitor 1b according to the third embodiment is configured to have capacitance with further reduced voltage-dependence as compared with the capacitor 1 according to the first embodiment.

A method for manufacturing the capacitor 1b according to the third embodiment is substantially the same as the method for manufacturing the capacitor 1a according to the second embodiment and is different only in that the conductive layer 3b is formed in place of the conductive layer 3a in the second step. In the method for manufacturing of the capacitor 1b according to the third embodiment, the conductive layer 3b is formed by, for example, CVD in the second step.

The method for manufacturing the capacitor 1b according to the third embodiment includes: preparing the silicon substrate 2 having the porous silicon region 23; forming the conductive layer 3b including a conductive polycrystalline silicon layer on the surface 231 of the porous silicon region 23; thereafter, forming a dielectric layer 4 on the conductive layer 3b; and thereafter, forming the electrode layer 5 on the dielectric layer 4. The method for manufacturing the capacitor 1b according to the third embodiment enables the voltage-dependence of the capacitance to be reduced.

### Variations

The first to third embodiments and the like are mere examples of various embodiments of the present disclosure. The first to third embodiments and the like may be modified in various manners depending on the design or the like as long as the object of the present disclosure is achieved.

For example, the shape of each of the plurality of pores 24 in the porous silicon region 23 is not particularly limited.

Moreover, on the silicon substrate 2, a plurality of circuits elements (e.g., MOSFETs) other than the capacitor 1, 1a, 1b may be disposed. That is, the capacitor 1, 1a, 1b according to the present disclosure is applicable to a semiconductor device including the capacitor 1, 1a, 1b, for example, an integrated circuit (IC) chip including the capacitor 1, 1a, 1b.

### Aspects

From the first to third embodiments and the like described above, the following aspects are disclosed in the present specification.

A capacitor (1; 1a; 1b) of a first aspect includes a silicon substrate (2), a conductive layer (3; 3a; 3b), a dielectric layer (4), and an electrode layer (5). The silicon substrate (2) has a first principal surface (21) and a second principal surface (22) opposite the first principal surface (21). The silicon substrate (2) has a porous silicon region (23) including a plurality of pores (24) formed in the first principal surface (21). The conductive layer (3; 3a; 3b) is disposed along a surface (231) of the porous silicon region (23). The dielectric layer (4) has a shape along the surface (231) of the porous silicon region (23) and is disposed on the conductive layer (3; 3a; 3b). The electrode layer (5) is disposed on the dielectric layer (4).

The capacitor (1; 1a; 1b) of the first aspect is configured to have capacitance with reduced voltage-dependence.

In a capacitor (1) of a second aspect referring to the first aspect, the conductive layer (3) is a diffusion layer disposed in the porous silicon region (23).

The capacitor (1) of the second aspect enables the conductive layer (3) to be easily formed, at the time of manufacturing, along the entire area of the surface (231) of the porous silicon region (23) and facilitates formation of the dielectric layer (4) and the electrode layer (5).

In a capacitor (1) of a third aspect referring to the second aspect, a carrier concentration of the diffusion layer is higher than a carrier concentration of the silicon substrate (2).

In a capacitor (1) of a fourth aspect referring to the second aspect, an impurity concentration of the diffusion layer is higher than an impurity concentration of the silicon substrate (2).

In a capacitor (1) of a fifth aspect referring to the fourth aspect, the impurity concentration of the silicon substrate (2) is higher than or equal to 1×10¹³ cm⁻³ and lower than or equal to 1×10¹⁷ cm⁻³, and the impurity concentration of the diffusion layer is higher than or equal to 1×10¹⁸ cm⁻³ and lower than or equal to 1×10²¹ cm³.

In a capacitor (1) of a sixth aspect referring to the fourth or fifth aspect, the silicon substrate (2) is a p-type silicon substrate, and an impurity in the diffusion layer is boron or indium.

In a capacitor (1) of a seventh aspect referring to the fourth or fifth aspect, the silicon substrate (2) is an n-type silicon substrate, and an impurity in the diffusion layer is phosphorus, arsenic, or antimony.

In a capacitor (1) of an eighth aspect referring to any one of the second to seventh aspects, the diffusion layer has a thickness of greater than or equal to 10 nm and less than or equal to 10000 nm.

A capacitor (1a) of a ninth aspect referring to the first aspect, the conductive layer (3a) is a metal layer disposed on the surface (231) of the porous silicon region (23).

The capacitor (1a) of the ninth aspect enables the voltage-dependence of capacitance to be further reduced.

In a capacitor (1a) of a tenth aspect referring to the ninth aspect, a material for the metal layer includes at least one selected from the group consisting of ruthenium, titanium, tantalum, tungsten, and aluminum.

In a capacitor (1a) of an eleventh aspect referring to the ninth or tenth aspect, the metal layer has a thickness of greater than or equal to 3 nm and less than or equal to 1000 nm.

In a capacitor (1b) of a twelfth aspect referring to the first aspect, the conductive layer (3b) is a conductive polycrystalline silicon layer.

The capacitor (1b) of the twelfth aspect enables the voltage-dependence of capacitance to be further reduced.

In a capacitor (1b) of a thirteenth aspect referring to the twelfth aspect, an impurity concentration of the conductive polycrystalline silicon layer is higher than an impurity concentration of the silicon substrate (2).

In a capacitor (1b) of the fourteenth aspect referring to the twelfth or thirteenth aspect, the silicon substrate (2) has an impurity concentration of higher than or equal to 1×10¹³ cm⁻³ and lower than or equal to 1×10¹⁷ cm⁻³, and the conductive polycrystalline silicon layer has an impurity concentration of higher than or equal to 1×10¹⁸ cm⁻³ and lower than or equal to 1×10²¹ cm⁻³.

A capacitor (1a) of a fifteenth aspect includes a silicon substrate (2), a conductive layer (3a), a dielectric layer (4), and an electrode layer (5). The silicon substrate (2) has a first principal surface (21) and a second principal surface (22) opposite the first principal surface (21). The silicon substrate (2) has a plurality of pores (24) formed in the first principal surface (21) and not reaching the second principal surface (22). The conductive layer (3a) has a shape along inner surfaces (241) of the plurality of pores (24) in the silicon substrate (2) and covering the inner surfaces (241) of the plurality of pores (24). The dielectric layer (4) has a shape along the inner surfaces (241) of the plurality of pores (24) in the silicon substrate (2) and covers the conductive layer (3a). The electrode layer (5) covers the dielectric layer (4).

The capacitor (1a) of the fifteenth aspect is configured to have capacitance with reduced voltage-dependence.

A method for manufacturing a capacitor (1) of a sixteenth aspect is a manufacturing method of the capacitor of any one of the second to eighth aspects and includes a first step, a second step, a third step, and a fourth step. The first step includes preparing the silicon substrate (2) having the porous silicon region (23). The second step includes forming the conductive layer (3) consisting of the diffusion layer along the porous silicon region (23). The third step includes forming the dielectric layer (4) on the conductive layer (3). The fourth step includes forming the electrode layer (5) on the dielectric layer (4).

The method for manufacturing the capacitor (1) of the sixteenth aspect enables the voltage-dependence of the capacitance to be reduced.

A method for manufacturing a capacitor (1a) of a seventeenth aspect is a manufacturing method of the capacitor (1a) of any one of the ninth to eleventh aspects and includes a first step, a second step, a third step, and a fourth step. The first step includes preparing the silicon substrate (2) having the porous silicon region (23). The second step includes forming the conductive layer (3a) consisting of the metal layer on the surface (231) of the porous silicon region (23). The third step includes forming the dielectric layer (4) on the conductive layer (3a). The fourth step includes forming the electrode layer (5) on the dielectric layer (4).

The method for manufacturing the capacitor (1a) of the seventeenth aspect enables the voltage-dependence of the capacitance to be reduced.

### REFERENCE SIGNS LIST

1, 1a, 1b Capacitor
2 Silicon Substrate
21 First Principal Surface
22 Second Principal Surface
23 Porous Silicon Region
231 Surface
24 Pore
241 Inner Surface
3, 3a, 3b Conductive Layer
4 Dielectric Layer
5 Electrode Layer

1. A capacitor comprising:
a silicon substrate having a first principal surface and a second principal surface opposite the first principal surface and having a porous silicon region including a plurality of pores formed in the first principal surface;
a conductive layer disposed along a surface of the porous silicon region;
a dielectric layer having a shape along the surface of the porous silicon region and disposed on the conductive layer; and
an electrode layer disposed on the dielectric layer.

2. The capacitor of claim 1, wherein
the conductive layer is a diffusion layer disposed in the porous silicon region.

3. The capacitor of claim 2, wherein
a carrier concentration of the diffusion layer is higher than a carrier concentration of the silicon substrate.

4. The capacitor of claim 2, wherein
an impurity concentration of the diffusion layer is higher than an impurity concentration of the silicon substrate.

5. The capacitor of claim 4, wherein
the impurity concentration of the silicon substrate is higher than or equal to 1×10¹³ cm⁻³ and lower than or equal to 1×10¹⁷ cm⁻³, and
the impurity concentration of the diffusion layer is higher than or equal to 1×10¹⁸ cm⁻³ and lower than or equal to 1×10²¹ cm⁻³.

6. The capacitor of claim 4, wherein
the silicon substrate is a p-type silicon substrate, and
an impurity in the diffusion layer is boron or indium.

7. The capacitor of claim 4, wherein
the silicon substrate is an n-type silicon substrate, and
an impurity in the diffusion layer is phosphorus, arsenic, or antimony.

8. The capacitor of claim 2, wherein
the diffusion layer has a thickness of greater than or equal to 10 nm and less than or equal to 10000 nm.

9. The capacitor of claim 1, wherein
the conductive layer is a metal layer disposed on the surface of the porous silicon region.

10. The capacitor of claim 9, wherein
a material for the metal layer includes at least one selected from the group consisting of ruthenium, titanium, tantalum, tungsten, and aluminum.

11. The capacitor of claim 9, wherein
the metal layer has a thickness of greater than or equal to 3 nm and less than or equal to 1000 nm.

12. The capacitor of claim 1, wherein
the conductive layer is a conductive polycrystalline silicon layer.

13. The capacitor of claim 12, wherein
an impurity concentration of the conductive polycrystalline silicon layer is higher than an impurity concentration of the silicon substrate.

14. The capacitor of claim 12, wherein
the silicon substrate has an impurity concentration of higher than or equal to 1×10¹³ cm⁻³ and lower than or equal to 1×10¹⁷ cm⁻³, and
the conductive polycrystalline silicon layer has an impurity concentration of higher than or equal to 1×10¹⁸ cm⁻³ and lower than or equal to 1×10²¹ cm⁻³.

15. A capacitor comprising:
a silicon substrate having a first principal surface and a second principal surface opposite the first principal surface and having a plurality of pores formed in the first principal surface and not reaching the second principal surface;
a conductive layer having a shape along inner surfaces of the plurality of pores in the silicon substrate and covering the inner surfaces of the plurality of pores;
a dielectric layer having a shape along the inner surfaces of the plurality of pores in the silicon substrate and covering the conductive layer; and
an electrode layer covering the dielectric layer.

16-17. (canceled)

18. A method for manufacturing the capacitor of claim 2, the method comprising:
preparing the silicon substrate having the porous silicon region;
forming the conductive layer consisting of the diffusion layer along the surface of the porous silicon region;
forming the dielectric layer on the conductive layer; and
forming the electrode layer on the dielectric layer.

19. A method for manufacturing the capacitor of claim 9, the method comprising:
preparing the silicon substrate having the porous silicon region;
forming the conductive layer consisting of the metal layer on the surface of the porous silicon region;
forming the dielectric layer on the conductive layer; and
forming the electrode layer on the dielectric layer.
